(19) United States
(12) Patent Application Publication
(10) Pub. No.: US 2005/0268961 A1
(43) Pub. Date: Dec. 8, 2005

(54) Photovoltaic device and method for manufacturing same

(75) Inventors: Kevin G. Hetzler, Sparta, NY (US); Alexander Tukachinsky, Holden, MA (US); Boris M. Friedman, Guttenberg, NJ (US); Paul W. Ortiz, Wayne, NJ (US)

Correspondence Address: TOLER & LARSON & ABEL L.L.P., 5000 PLAZA ON THE LAKE STE 265, AUSTIN, TX, 78746, US

(73) Assignee: Saint-Gobain Performance Plastics Coporation

(21) Appl. No.: 10/862,121

(22) Filed: Jun. 4, 2004

(51) Int. Cl. H01L 31/00

(52) U.S. Cl. 136/251; 438/64

(57) ABSTRACT

The disclosure is directed to a photovoltaic device including a photovoltaic layer, a first fluoropolymer layer, and a second fluoropolymer layer. The first fluoropolymer layer overlies an active side of the photovoltaic layer. The second fluoropolymer layer overlies the first polymer layer. The second fluoropolymer layer has a melting point greater than 135° C. and the first fluoropolymer layer has a melting point less than 135° C.

### TECHNICAL FIELD OF THE DISCLOSURE

This application in general relates to photovoltaic devices and methods for manufacturing photovoltaic devices.

### BACKGROUND

As economies around the world grow, demand for energy is increasing. As a result, the price of traditional fossil fuel energy sources is increasing. However, increased usage of fossil fuel sources has disadvantages such as detrimental environmental impact and theorized limits in supply.

Governments and energy industries are looking toward alternative energy sources for fulfilling future supply requirements. However, alternate energy sources have a higher per kilowatt-hour cost than traditional fossil fuel sources. One such alternate energy source is solar power. In typical solar power systems, photovoltaic devices absorb sunlight to produce electrical energy. Typical photovoltaic devices have used polymer laminates or glass to protect the active side of the photovoltaic cell. However, typical polymer laminates and glass have either poor mechanical properties or poor aging properties. For example, glass may be subject to mechanical damage through impact or scratching. Polymer laminates such as ethyl vinyl acetate (EVA) may degrade, reducing optical clarity and producing corrosive byproducts. Both mechanical failure and chemical degradation reduce the life of the photovoltaic cell and the quantity of power produced by the photovoltaic cell, increasing the cost per kilowatt-hour over the life of the photovoltaic device. As such, an improved photovoltaic device would be desirable.

### SUMMARY

In one particular embodiment, the disclosure is directed to a photovoltaic device including a photovoltaic layer, a first fluoropolymer layer, and a second fluoropolymer layer. The first fluoropolymer layer overlies an active side of the photovoltaic layer. The second fluoropolymer layer overlies the first polymer layer. The second fluoropolymer layer has a melting point greater than 135° C. and the first fluoropolymer layer has a melting point less than 135° C.

In another exemplary embodiment, the disclosure is directed to a method of manufacturing a photovoltaic device. The method includes heating a first polymer film and applying the first polymer film to overlie a photovoltaic layer. The first polymer film includes at least two coextruded fluoropolymer layers. The first polymer film is heated to at least a melting point of a first layer of the at least two coextruded fluoropolymer layers.

In a further exemplary embodiment, the disclosure is directed to a photovoltaic device that includes a photovoltaic layer and a first polymer film. The first polymer film overlies the photovoltaic layer and includes at least two coextruded fluoropolymer layers.

### BRIEF DESCRIPTION OF THE DRAWINGS

FIGS. 1 and 2 illustrate exemplary embodiments of a photovoltaic device.

FIG. 3 illustrates an exemplary method for manufacturing a photovoltaic device.

FIG. 4 illustrates an exemplary apparatus for manufacturing a photovoltaic device.

### DETAILED DESCRIPTION

In one embodiment, a photovoltaic device is provided that includes a photovoltaic layer and a first polymer film. The first polymer film overlies the photovoltaic layer and includes at least two coextruded fluoropolymer layers. The first polymer film overlies an active surface of the photovoltaic layer. In another embodiment, the first polymer film overlies a back surface of the photovoltaic layer. In either case, an overlying film or layer is generally in direct contact with the underlying layer, although alternate embodiments may have intervening layers between the overlying layer and the underlying layer.

The photovoltaic device may be manufactured by heating the first polymer film to at least the lower melting point of the two coextruded fluoropolymer layers, followed by applying the layers, such as by pressing or rolling to overlie a photovoltaic layer. For example, the first polymeric film may be hot-rolled onto a photovoltaic layer in a continuous process. In another example, the first polymeric layer may be pressed onto a photovoltaic layer in a batch or semi-continuous process, described in more detail below.

The first and second fluoropolymers of the at least two coextruded fluoropolymer layers, respectively, may be formed of polymers and copolymers formed of fluorinated monomers. Copolymers include graft copolymers, alternating copolymers, random copolymers, and block copolymers. Exemplary fluoropolymers may be formed of monomers including tetrafluoroethylene (TFE), hexafluoropropylene (HFP), perfluoropropyl or perfluoromethyl vinyl ether, chlorotrifluoroethylene (CTFE), vinylidene fluoride (VF₂ or VDF), and vinyl fluoride (VF). The fluoropolymers may include polymers, polymer blends and copolymers including one or more of the above monomers, such as fluorinated ethylene propylene (FEP), ethylene-tretrafluoroethylene (ETFE), poly tetrafluoroethylene-perfluoropropylether (PFA), poly tetrafluoroethylene-perfluoromethylvinylether (MFA), poly tetrafluoroethylene (PTFE), poly vinylidene fluoride (PVDF), ethylene chloro-trifluoroethylene (ECTFE), poly chloro-trifluoroethylene (PCTFE), and tetrafluoroethylene-hexafluoropropylene-vinylidene fluoride (THV). In further exemplary embodiments, the fluoropolymers may be copolymers of alkene monomers with fluorinated monomers, such as Daikin™ EFEP copolymer by Daikin America, Inc.

Generally, each of the at least two coextruded fluoropolymer layers are primarily formed of respective fluoropolymers, such that, in the case of polymer blends, non-fluorinated polymers are limited to less than 15 wt %, such as less than 10 wt %, less than 5 wt % or less than 2 wt % of the total polymer content. In a certain embodiment, the polymeric content of the at least two coextruded layers is essentially 100% fluoropolymer. In some embodiments, the layers consist essentially of the respective fluoropolymers described above. As used herein, the phrase “consists essentially of” used in connection with the fluoropolymers precludes the presence of non-fluorinated polymers that affect the basic and novel characteristics of the fluoropolymer, although, commonly used processing agents and additives such as antioxidants, fillers, UV agents, dyes, and anti-aging agents may be used in the polymeric layers.

In one particular embodiment, the first and second fluoropolymers may be copolymers formed of the monomers TFE, HFP, and VDF, such as THV copolymer. The THV copolymer may include Dyneon™ THV 220, Dyneon™ THV 2030GX, Dyneon™ THV 500G, Dyneon™ THV X815G, or Dyneon™ THV X610G. For example, the copolymer may include about 20-70 wt % VDF monomer, such as about 35-65 wt % VDF monomer. The copolymer may include about 15-80 wt % TFE monomer, such as about 20-55 wt % TFE monomer. In addition, the copolymer may include about 15-75 wt % HFP monomer, such as about 20-65 wt %. In one embodiment, a lower melting point copolymer includes at least 50 wt % VDF monomer, such as about 55 wt % VDF monomer or about 60 wt % VDF monomer. In another embodiment, the higher melting point copolymer includes not more than about 50 wt % VDF monomer, such as not more than about 45 wt % VDF monomer or not more than about 40 wt % VDF monomer.

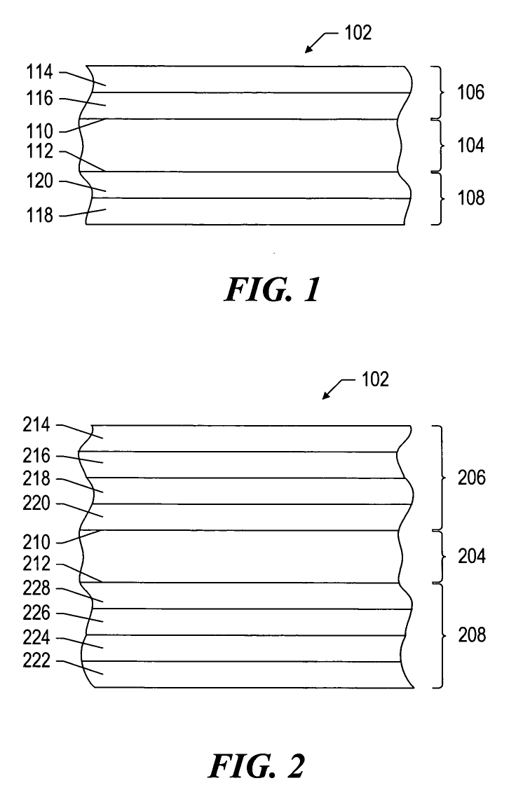

FIG. 1 illustrates an exemplary embodiment of a photovoltaic device. The photovoltaic device 102 includes a photovoltaic layer or layers 104 surrounded by protective films 106 and 108. The photovoltaic layers 104 include an active surface 110 and a backside surface 112. When in service, the photovoltaic layer 104 may receive electromagnetic radiation through the active surface 110 and using devices, such as semiconductor devices formed in the photovoltaic layer or layers 104, convert the electromagnetic radiation into electric potential. In general, light or electromagnetic radiation transmitted or passed to the backside surface 112 through protective film 108 does not result in the production of a significant electric potential.

The polymeric films 106 and 108 may have a thickness of at least about 2 mils. For example, the polymeric films 106 and 108 may have a thickness of at least about 3 mils, at least about 5 mils, or greater. In one exemplary embodiment, the polymeric films, such as films 106 and 108, include coextruded fluoropolymer layers.

The photovoltaic layer or layers 104 may be formed of rigid substrates or flexible substrates. For example, rigid substrates include crystalline silicon. Flexible substrates include metal substrates, such as titanium, amorphous silicon substrates, and polymeric substrates. Photoactive devices, such as electronic devices, may be formed on the substrates using techniques such as semiconductor processing techniques and printing techniques. These photoactive devices may be connected using conductive interconnects, such as metallic interconnects and/or semiconductor interconnects. Metallic interconnects, for example, include gold, silver, titanium, or copper interconnects. In addition, the photovoltaic layers 104 may or may not include a hard coating layer on the active surface 112 that acts to protect the photovoltaic layer or layers during additional processing.

As depicted in the exemplary embodiment of FIG. 1, the protective film 106 may overlie the active surface 110 of the photovoltaic layer or layers 104 and a protective film 108 may underlie the backside 112 of the photovoltaic layer or layers 104. In this particular embodiment, film 106 includes two coextruded layers 114 and 116. These coextruded layers may be formed of fluoropolymer, such as PVDF, ETFE, or THV.

In one feature, layer 114 may have a melting point at least about 10° C. higher than the melting point of layer 116. For example, the melting point of fluoropolymer layer 114 may be at least about 25° C. higher, at least about 40° C. higher, at least about 60° C. higher, or at least about 100° C. higher than the melting point of fluoropolymer layer 116.

Further, the fluoropolymer layer 114 may have a melting point greater than 135° C. and the fluoropolymer layer 116 may have a melting point less than 135° C. For example, the fluoropolymer layer 114 may have a melting point of at least about 165° C., at least about 180° C., or at least about 220° C. The fluoropolymer layer 116 may have a melting point no more than about 135° C., no more than about 120° C. or no more than about 115° C.

In addition, the fluoropolymer layer 114 may have a greater fluorinated percentage than the fluoropolymer layer 116. For example, the fluoropolymer layer 114 includes a greater number of fluorine atoms than the fluoropolymer layer 116. Additionally or alternately, the fluoropolymer layer 114 includes a greater percentage of fluorinated carbons than fluoropolymer layer 116.

In one particular embodiment, the fluoropolymer layer 114 and the fluoropolymer layer 116 are formed of THV copolymer. The fluoropolymer layer 114 may, for example, have a higher percentage of HFP than the fluoropolymer layer 116. In another exemplary embodiment, the fluoropolymer layer 114 may have a higher percentage of TFE than the fluoropolymer layer 116. In a further exemplary embodiment, the fluoropolymer layer 114 may have a lower percentage of VDF than the fluoropolymer layer 116.

In one embodiment, layer 114 is formed of a THV block copolymer, such as Dyneon™ THV 500G, Dyneon™ THV X815G or Dyneon™ THV X610G, while layer 116 is formed of Dyneon™ THV 220 or PVDF. For example, polymeric film 106 may be formed of a THV layer 114 and a PVDF layer 116. In other exemplary embodiments, layer 114 may be formed of PVDF, THV, ETFE, EFEP or PCTFE and layer 116 may be formed of PVDF or THV.

The polymeric film 106 overlies the active surface 110 of the photovoltaic layer or layers 104. To facilitate light transmission to the active surface, the polymeric film 106 generally has an optical clarity of at least about 85% light transmission. For example, the polymeric film 106 may have an optical clarity of at least about 85% light transmission of light in the visible spectrum, such as between about 100 nm to about 1000 nm or about 380 nm to 770 nm. In further embodiments, the optical clarity of the polymeric film 106 may permit at least about 90%, such as at least about 92% or even at least about 95% of light transmission. Clarity may even be higher, such as at least about 98% or at least 99% light transmission. The optical clarity may, for example, be measured by a BYK-Gardner Haze-Gard Plus.

Polymeric film 108 may have two layers, 118 and 120. In one exemplary embodiment, the fluoropolymer film 108 comprises the same materials as the fluoropolymer film 106. In an alternative embodiment, polymer film 108 may have a different structure to polymer film 106 and be laminated or adhered to the backside surface 112 of the photovoltaic layer or layers 104.

In an alternative embodiment, additional films may be added to overlie polymer film 106 or underlie polymer film 108. In one exemplary embodiment, an additional fluoropolymer film, such as an ETFE film, may be laminated or adhered to overlie polymer film 106. In another exemplary embodiment, a PCTFE film may be laminated to overlie polymer film 106 or underlie polymer film 108.

FIG. 2 illustrates another embodiment of a photovoltaic device. In the photovoltaic device 202, polymeric films 206 and 208 are laminated or adhered to photovoltaic layer 204. The photovoltaic layer 204 includes an active surface 210 and a backside surface 212. The photovoltaic layer or layers 204 have a similar construction to the photovoltaic layer or layers described above.

Polymeric film 206 includes polymeric layers 214, 216, 218 and 220. The polymeric film 206 may be a coextruded film and include at least two coextruded fluoropolymer layers. For example, layers 218 and 220, layers 216 and 220, layers 214 and 218, or various combinations of two or more layers may include fluoropolymer layers.

In one particular embodiment, layers 218 and 220 are fluoropolymer layers having a melting point difference of at least about 10° C. For example, layer 218 may have a melting point at least about 25° C. higher, at least about 40° C. higher, at least about 60° C. higher, or at least about 100° C. higher. The fluoropolymer layer 218 may have a melting point greater than 135° C. and fluoropolymer layer 220 may have a melting point less than 135° C. For example, fluoropolymer layer 218 may have a melting point of at least about 160° C., at least about 180° C., or at least about 220° C. Fluoropolymer layer 220 may have a melting point not greater than about 135° C., such as not greater than about 125° C., not greater than about 120° C., or not greater than about 115° C.

In one exemplary embodiment, polymeric film 206 is formed of layer 220 including a fluoropolymer, such as Dyneon™ THV 220, Dyneon™ THV 2030GX or PVDF. Layer 218 is formed of a THV copolymer, such as Dyneon™ THV 500G, Dyneon™ THV X815G, or Dyneon™ THV X610G. Layer 216 may be formed of a fluoropolymer, such as PCTFE, and layer 214 may be formed of fluoropolymer such as ETFE or Daikin™ EFEP.

The photovoltaic device 202 may include a polymeric film 208 laminated or adhered to the backside 212 of photovoltaic layer or layers 204. The polymeric film 208 may include at least two coextruded fluoropolymer layers, such as layers 228 and 226, 228 and 224, 226 and 222, or combinations of two or more of these layers. The at least two coextruded fluoropolymer layers may include one layer having a higher melting point than another layer. For example, layer 226 may have a higher melting point than layer 228. As such, polymeric film 208 may have a similar construction to polymeric film 206.

The polymeric film overlying a photovoltaic layer or layers may provide optical clarity, such as least about 85% light transmission in the visible spectrum. For example, the polymeric film may have an optical clarity of at least 95% light transmission.

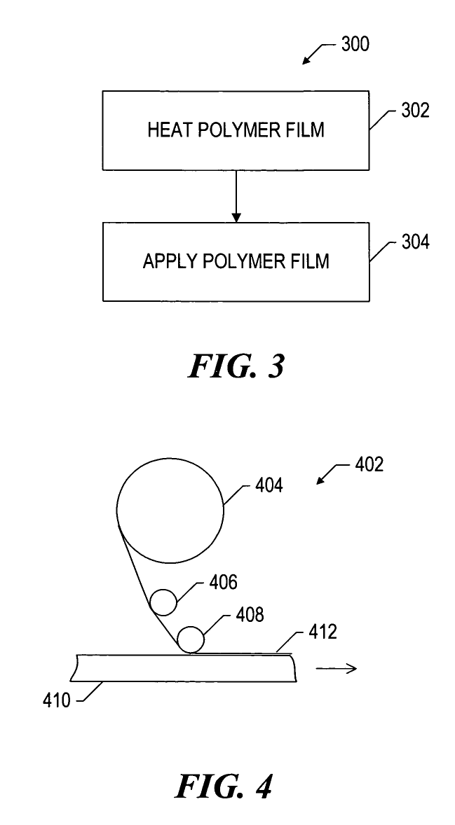

The polymeric device may be formed through the method illustrated in FIG. 3. The method 300 includes heating the polymer film, as shown at step 302. The polymeric film may be heated to a temperature at least about the melting point of a first fluoropolymer layer, while being less than the melting point of a second fluoropolymer layer. The polymeric film is applied to the photovoltaic layers, as shown at step 304. Upon cooling, the polymer film adheres to, or is laminated to the photovoltaic layers. Such a method may be used in the continuous processing of photovoltaic devices.

FIG. 4 depicts one exemplary continuous process, such as hot rolling. A roll of polymeric film 404 that includes at least two fluoropolymer layers is provided. The film 404 is heated at hot roller 406 and is pressed to a photovoltaic layer or layers 410 by roller 408. In another embodiment, this process may be repeated to laminate a second side of the polymeric layers or photovoltaic layers 410.

In alternative embodiments, the polymeric film may be applied to the photovoltaic layer and then heated to a temperature at least about the melting point of the lowest melting fluoropolymer layer. This alternative method may be used in batch or semi-batch processing of photovoltaic devices.

In a further exemplary embodiment, the polymeric film is formed of fluorinated polymers and is often times free of chlorinated flouropolymers. Certain embodiments expressly preclude chlorinated fluoropolymers. In another exemplary embodiment, the film has an optical clarity greater than 95% light transmission, such as greater than 96% light transmission.

### EXAMPLES

An exemplary embodiment of a multi-layer polymer film, including a first fluoropolymer layer that has a lower melting point than a second fluoropolymer layer. The fluoropolymer layers are coextruded as illustrated by Example 1.

### Example 1

Fluoropolymer Dyneon™ THV X815G, with a melting point of 224° C., was processed on a ¾ inch Brabender extruder at 8 rpm. The temperatures by zone of the Brabender extruder were 220° C., 270° C., 260° C., and 260° C. Two additional layers were formed using fluoropolymer Dyneon™ THV 220G, having a melting point of 116° C. One layer of the two layers was processed on a 1″Killion extruder at 12 rpm. The temperatures by zone of the Killion extruder were 120° C., 170° C., 220° C., and 220° C. The other layer of the two layers was processed on a ¾ Brabender extruder at 8 rpm, and the temperatures by zone of the Brabender extruder were 120° C, 170° C., 220° C., and 220° C. The extruders fed an ABC-type feedblock held at a temperature of 240° C. and a die held at 230° C.

Exemplary films of 2 mil and 5 mil thickness having effectively two-layers, a Dyneon™ THV X815G layer and a Dyneon™ THV 220G layer, were produced with a thickness layer ratio (THV 815: THV 220) equal to 20:80. The film may be heated to a temperature of 135° C. and applied to a photovoltaic layer wherein the Dyneon™ THV 220G layer is closer to the photovoltaic layer than the Dyneon™ THVX815G layer.

The above-disclosed subject matter is to be considered illustrative, and not restrictive, and the appended claims are intended to cover all such modifications, enhancements, and other embodiments, which fall within the true scope of the present invention. Thus, to the maximum extent allowed by law, the scope of the present invention is to be determined by the broadest permissible interpretation of the following claims and their equivalents, and shall not be restricted or limited by the foregoing detailed description.

1. A photovoltaic device comprising:
a photovoltaic layer;
a first fluoropolymer layer overlying an active side of the photovoltaic layer and having a melting point less than 135° C.; and
a second fluoropolymer layer overlying the first fluoropolymer layer and having a melting point greater than 135° C.

2. The photovoltaic device of claim 1, wherein the first fluoropolymer layer is in direct contact with the active side of the photovoltaic layer.

3. The photovoltaic device of claim 1, wherein the fist fluoropolymer layer and the second fluoropolymer layer are coextruded.

4. The photovoltaic device of claim 1, wherein the first fluoropolymer layer and the second fluoropolymer layer have optical clarity of at least 85% light transmission.

5. The photovoltaic device of claim 1, wherein the second fluoropolymer layer has a melting point at least about 10° C. higher than a melting point of the first fluoropolymer layer.

6. The photovoltaic device of claim 1, wherein the second fluoropolymer layer has a melting point at least about 25° C. higher than a melting point of the first fluoropolymer layer.

7. The photovoltaic device of claim 1, wherein the second fluoropolymer layer has a melting point at least about 40° C. higher than a melting point of the first fluoropolymer layer.

8. The photovoltaic device of claim 1, wherein the second fluoropolymer layer has a melting point at least about 60° C. higher than a melting point of the first fluoropolymer layer.

9. The photovoltaic device of claim 1, wherein the second fluoropolymer layer has a melting point greater than about 160° C.

10. The photovoltaic device of claim 1, wherein the second fluoropolymer layer has a melting point greater than about 180° C.

11. The photovoltaic device of claim 1, wherein the second fluoropolymer layer has a melting point greater than about 220° C.

12. The photovoltaic device of claim 1, wherein the second fluoropolymer layer has a greater fluorinated percentage than the first fluoropolymer layer.

13. The photovoltaic device of claim 1, wherein the first fluoropolymer layer comprises THV copolymer.

14. The photovoltaic device of claim 1, wherein the second fluoropolymer layer comprises THV copolymer.

15. The photovoltaic device of claim 1, further comprising a third fluoropolymer layer overlying the second fluoropolymer layer.

16. The photovoltaic device of claim 15, wherein the third fluoropolymer layer comprises ETFE, EFEP or PCTFE.

17. The photovoltaic device of claim 1, further comprising a third fluoropolymer layer underlying the photovoltaic layer.

18. The photovoltaic device of claim 1, wherein the first and second fluoropolymer layers consist essentially of respective first and second fluoropolymers.

19. The photovoltaic device of claim 1, wherein the first and second fluoropolymer layers are free of chlorinated fluoropolymer.

20. A method of manufacturing a photovoltaic device, the method comprising:
heating a first polymer film comprising at least two coextruded fluoropolymer layers to at least a melting point of a first layer of the at least two coextruded fluoropolymer layers; and
applying the polymer film to overlie a photovoltaic layer.

21. The method of claim 20, wherein applying the polymer film comprises hot rolling.

22. The method of claim 20, wherein the first polymer film has optical clarity of at least 85% light transmission.

23. The method of claim 20, wherein heating the first polymer film comprises heating the first polymer film to a temperature less than the melting point of a second layer of the at least two coextruded fluoropolymer layers.

24. The method of claim 20, wherein the first layer of the at least two coextruded fluoropolymer layers has a melting point at least about 10° C. lower than a melting point of a second layer of the at least two coextruded fluoropolymer layers.

25. The method of claim 24, wherein the first layer is applied to overlie the photovoltaic layer closer than the second layer.

26. The method of claim 20, wherein the first layer of the at least two coextruded fluoropolymer layers has a melting point less than 135° C. and a second layer of the at least two coextruded fluoropolymer layers has a melting point greater than 135° C.

27. The method of claim 26, wherein heating the first polymer film comprises heating the first polymer film to at least about 135° C.

28. The method of claim 20, wherein the first layer of the at least two coextruded fluoropolymer layers has a lower fluorinated percentage than a second layer of the at least two coextruded fluoropolymer layers.

29. The method of claim 20, further comprising applying a second polymer film overlying the first polymer film, the second polymer film comprising a fluoropolymer.

30. The method of claim 20, further comprising applying a second polymer film to underlie the photovoltaic layer.

31. A photovoltaic device comprising:
a photovoltaic layer; and
a first polymer film overlying the photovoltaic layer, the polymer film comprising at least two coextruded fluoropolymer layers.

32. The photovoltaic device of claim 31, wherein the first polymer film has optical clarity of at least 85% light transmission.

33. The photovoltaic device of claim 31, wherein the first polymer film is in direct contact with the photovoltaic layer.

34. The photovoltaic device of claim 31, wherein a first layer of the at least two coextruded fluoropolymer layers has a melting point at least about 10° C. lower than a melting point of a second layer of the at least two coextruded fluoropolymer layers.

35. The photovoltaic device of claim 34, wherein the first layer is closer than the second layer to the photovoltaic layer, such that the second layer overlies both the first layer and the photovoltaic layer.

36. The photovoltaic device of claim 31, wherein a first layer of the at least two coextruded fluoropolymer layers has a melting point less than 135° C. and a second layer of the at least two coextruded fluoropolyrner layers has a melting point greater than 135° C.

37. The photovoltaic device of claim 31, wherein a first layer of the at least two coextruded fluoropolymer layers has a lower fluorinated percentage than a second layer of the at least two coextruded fluoropolymer layers.

38. The photovoltaic device of claim 31, wherein each of the at least two coextruded fluoropolymer layers consist essentially of fluoropolyrner.

39. The photovoltaic device of claim 31, wherein each of the at least two coextruded fluoropolymer layers are free of chlorinated fluoropolymer.
